(19) United States
(12) Patent Application Publication
(10) Pub. No.: US 2025/0201584 A1
(43) Pub. Date: Jun. 19, 2025

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Yusaku OKAJIMA, Toyama-shi (JP)

(73) Assignee: Kokusai Electric Corporation, Tokyo (JP)

(21) Appl. No.: 19/063,635

(22) Filed: Feb. 26, 2025

Related U.S. Application Data
(63) Continuation of application No. PCT/JP2022/035792, filed on Sep. 26, 2022.

(51) Int. Cl. H01L 21/67; C23C 16/34; C23C 16/455; C23C 16/52; H01L 21/02

(52) U.S. Cl. CPC H01L 21/67017; C23C 16/345; C23C 16/45544; C23C 16/52; H01L 21/0228

(57) ABSTRACT

It is possible to suppress variations in a supply amount of a process gas within a surface of a substrate. There is provided a technique that includes: a process chamber in which a substrate is processed; a substrate support configured to support the substrate; a first flow passage through which a gas is supplied to the process chamber along an inner wall surface of the process chamber; and a second flow passage, through which the gas is supplied to the process chamber, arranged beside the first flow passage, wherein the second flow passage is configured such that a center of the process chamber is located within an extended region created by extending the second flow passage further toward the process chamber.

### CROSS-REFERENCE TO RELATED PATENT APPLICATION

This application is a bypass continuation application of PCT International Application No. PCT/JP2022/035792, filed on Sep. 26, 2022, in the WIPO, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

In a substrate processing apparatus according to some related arts, a process gas is supplied in a direction toward an outer periphery of a substrate rather than in a direction toward a center of the substrate.

A vortex flow of a gas such as the process gas may occur around an inner wall of a process chamber in which the substrate is processed. In such a case, variations in a supply amount of the process gas may occur between the center and the outer periphery of the substrate.

### SUMMARY

According to the present disclosure, there is provided a technique capable of suppressing variations in a supply amount of a process gas within a surface of a substrate.

According to an embodiment of the present disclosure, there is provided a technique that includes: a process chamber in which a substrate is processed; a substrate support configured to support the substrate; a first flow passage through which a gas is supplied to the process chamber along an inner wall surface of the process chamber; and a second flow passage, through which the gas is supplied to the process chamber, arranged beside the first flow passage, wherein the second flow passage is configured such that a center of the process chamber is located within an extended region created by extending the second flow passage further toward the process chamber.

### BRIEF DESCRIPTION OF THE DRAWINGS

FIG. 1 is a diagram schematically illustrating a vertical cross-section of a substrate processing apparatus according to a first embodiment of the present disclosure.

FIG. 2 is a diagram schematically illustrating a horizontal cross-section of a gas supplier according to the first embodiment of the present disclosure.

FIG. 3 is a diagram schematically illustrating a vertical cross-section of the gas supplier according to the first embodiment of the present disclosure.

FIG. 4 is a block diagram schematically illustrating a configuration of a controller and related components of the substrate processing apparatus according to the first embodiment of the present disclosure.

FIG. 5 is a flow chart schematically illustrating a flow of a substrate processing according to the first embodiment of the present disclosure.

FIG. 6 is a diagram schematically illustrating a horizontal cross-section of a gas supplier according to a second embodiment of the present disclosure.

FIG. 7 is a diagram schematically illustrating a horizontal cross-section of a gas supplier according to a third embodiment of the present disclosure.

FIG. 8A is a diagram schematically illustrating an operation of accommodating a nozzle used as the gas supplier in a housing structure according to the third embodiment of the present disclosure, when viewed from above, and FIG. 8B is a diagram schematically illustrating a state in which the nozzle shown in FIG. 8A is accommodated in the housing structure, when viewed from above.

FIG. 9 is a diagram schematically illustrating a vertical cross-section of the gas supplier according to the third embodiment of the present disclosure.

FIGS. 10A and 10B are diagrams schematically illustrating modified examples of the gas supplier according to the embodiments of the present disclosure.

### DETAILED DESCRIPTION

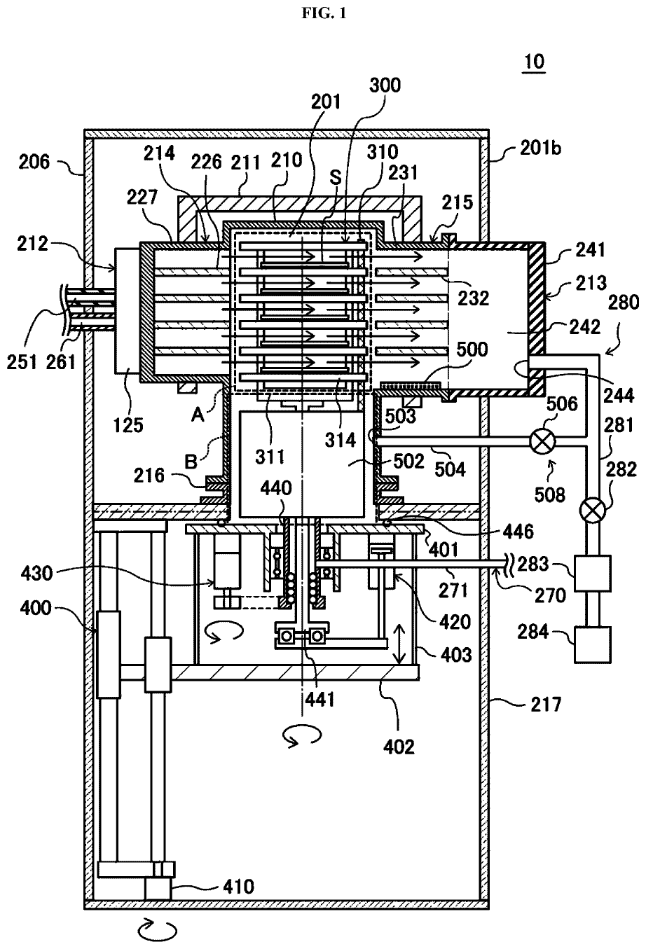

Hereinafter, one or more embodiments (also simply referred to as “embodiments”) according to the technique of the present disclosure will be described mainly with reference to FIGS. 1 to 10B. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

First, a first embodiment according to the technique of the present disclosure will be described. A configuration of a substrate processing apparatus 10 according to the present embodiment will be described with reference to FIG. 1.

The substrate processing apparatus 10 includes a reaction tube storage chamber 206. In the reaction tube storage chamber 206, a reaction tube 210 of a cylindrical shape extending in a vertical direction, a heater 211 serving as a heating structure (furnace body) installed on an outer periphery of the reaction tube 210, a gas supply structure 212 serving as a part of a gas supplier (which is a gas supply system), and a gas exhaust structure 213 serving as a part of a gas exhauster (which is a gas exhaust system) are provided. The gas supplier may further include a component such as an upstream side gas guide 214 described later. Further, the gas exhauster may further include a component such as a downstream side gas guide 215 described later.

The gas supply structure 212 is provided upstream in a gas flow direction and beside the reaction tube 210. A gas such as a process gas is supplied into a process chamber 201 in the reaction tube 210 from outside the heater 211 through the gas supply structure 212. Then, the gas is supplied to a substrate S in a horizontal direction. The gas exhaust structure 213 is provided downstream in the gas flow direction and beside the reaction tube 210, and the gas in the reaction tube 210 is discharged (exhausted) through the gas exhaust structure 213. The gas exhaust structure 213 is disposed opposite to the gas supply structure 212 with the reaction tube 210 interposed therebetween.

The upstream side gas guide 214 configured to adjust a flow of the gas supplied through the gas supply structure 212 is provided on an upstream side of the reaction tube 210. In addition, the downstream side gas guide 215 configured to adjust the flow of the gas discharged from the reaction tube 210 is provided on a downstream side of the reaction tube 210. A lower end of the reaction tube 210 is supported by a manifold 216.

The reaction tube 210, the upstream side gas guide 214 and the downstream side gas guide 215 are implemented as a continuous structure such that they communicate with one another in the horizontal direction. For example, each of the reaction tube 210, the upstream side gas guide 214 and the downstream side gas guide 215 is made of a material such as quartz and silicon carbide (SiC). In addition, each of the reaction tube 210, the upstream side gas guide 214 and the downstream side gas guide 215 is constituted by a heat transmittable structure capable of transmitting a heat radiated from the heater 211. The heat of the heater 211 can heat the substrate S and the gas.

The upstream side gas guide 214 includes a housing 227 and a partition plate 226. The partition plate 226 extends in the horizontal direction. The “horizontal direction” of the partition plate 226 may refer to a direction toward a side wall of the housing 227. A plurality of partition plates including the partition plate 226 are arranged in the vertical direction. Hereafter, the plurality of partition plates including the partition plate 226 may also be simply referred to as “partition plates 226”. The partition plate 226 is fixed to the side wall of the housing 227 such that it is possible to prevent the gas from flowing beyond the partition plate 226 into an adjacent region below or above the partition plate 226. By preventing the gas from flowing beyond the partition plate 226, it is possible to reliably form a flow of the gas (also referred to as a “gas flow”) described later.

The partition plates 226 are provided at positions corresponding to a plurality of substrates including the substrate S, respectively, with the plurality of substrates supported by a substrate support structure 300 described later. Hereinafter, the plurality of substrates including the substrate S may also be referred to as “substrates S”.

The downstream side gas guide 215 is configured such that a ceiling thereof is provided above an uppermost substrate among the substrates S supported by the substrate support structure 300, and a bottom thereof is provided below a lowermost substrate among the substrates S supported by the substrate support structure 300. The substrate support structure 300 is used as a substrate support (substrate retainer) capable of supporting the substrates S.

The downstream side gas guide 215 includes a housing 231 and a partition plate 232. The partition plate 232 extends in the horizontal direction. The “horizontal direction” of the partition plate 232 may refer to a direction toward a side wall of the housing 231. Further, a plurality of partition plates including the partition plate 232 are arranged in the vertical direction. Hereafter, the plurality of partition plates including the partition plate 232 may also be simply referred to as “partition plates 232”. The partition plate 232 is fixed to the side wall of the housing 231 such that it is possible to prevent the gas from flowing beyond the partition plate 232 into an adjacent region below or above the partition plate 232. By preventing the gas from flowing beyond the partition plate 232, it is possible to reliably form the gas flow described later.

The upstream side gas guide 214 communicates with a space within the downstream side gas guide 215 via the process chamber 201. A ceiling of the housing 227 is provided at the same height as a ceiling of the housing 231. In addition, a bottom of the housing 227 is provided higher than a bottom of the housing 231.

The partition plates 232 are provided at positions corresponding to the substrates S and the partition plates 226 related thereto, respectively, with the substrates S supported by the substrate support structure 300. It is preferable that the partition plate 226 and the partition plate 232 corresponding to the partition plate 226 are provided at the same height. In addition, when processing the substrate S, it is preferable that the substrate S, the partition plate 226 corresponding to the substrate S and the partition plate 232 corresponding to the partition plate 226 are provided at the same height.

By providing the partition plates 226 and the partition plates 232, it is possible to uniformize a pressure loss in the vertical direction at both an upstream and a downstream of each of the substrates S. As a result, it is possible to reliably form a horizontal gas flow over the partition plate 226, the substrate S and the partition plate 232 while suppressing a vertical gas flow.

The gas exhaust structure 213 is provided downstream of the downstream side gas guide 215. The gas exhaust structure 213 is constituted mainly by a housing 241 and an exhaust hole 244. The exhaust hole 244 is provided at a downstream side of the housing 241 on a lower portion of the housing 241 in the horizontal direction. An exhaust pipe 281 is connected to the process chamber 201 via the exhaust hole 244.

The gas exhaust structure 213 communicates with the space within the downstream side gas guide 215. The housing 231 and the housing 241 may form a structure with a continuous height. That is, a height of the ceiling of the housing 231 is configured to be the same as that of a ceiling of the housing 241, and a height of the bottom of the housing 231 is configured to be the same as that of a bottom of the housing 241. The housing 231 is configured such that a thermocouple 500 can be installed on the bottom of the housing 231.

The gas exhaust structure 213 is provided in a lateral direction of the reaction tube 210, and is a lateral exhaust structure configured to exhaust the gas along a lateral direction of the substrate S.

The process chamber 201 includes: a processing region A in which the substrate S is processed; and a heat insulating region B below the processing region A, in which a heat insulator (which serves as a heat insulating structure) 502 described later is disposed while the substrate support structure 300 is transferred (loaded) into the process chamber 201. Thereby, it is possible to prevent (or suppress) an inert gas supplied to the heat insulator 502 or an atmosphere (including reaction by-products) of the heat insulating region B from entering (or flowing into) the processing region A. Therefore, the gas flow passing through each of the substrates S is formed in the horizontal direction toward the gas exhaust structure 213 while suppressing the gas flow in the vertical direction.

That is, the gas that has passed through the downstream side gas guide 215 is exhausted through the exhaust hole 244. When the gas is exhausted through the exhaust hole 244, since the gas exhaust structure 213 is not provided with a structure similar to the partition plate described above, the gas flow whose vertical component is non-zero is formed toward the exhaust hole 244.

The substrate support structure 300 includes a partition plate support 310 and a base structure 311, and is accommodated in the reaction tube 210. The substrates S are arranged directly below an inner wall of a top plate of the reaction tube 210. In addition, the substrate support structure 300 is configured such that a process of moving the substrate S from the substrate support structure 300 by a vacuum transfer robot (not shown) in a transfer chamber 217 via a substrate loading/unloading port (not shown) can be performed and a process of loading the substrate S (which is moved from the substrate support structure 300) into the reaction tube 210 and forming a film on a surface of the substrate S can be performed. For example, the substrate loading/unloading port is provided on a side wall of the transfer chamber 217.

A plurality of partition plates including a partition plate 314 of a disk shape are fixed to the partition plate support 310 at a predetermined pitch therebetween. Hereafter, the plurality of partition plates including the partition plate 314 may also be simply referred to as “partition plates 314”. The substrates S are placed between the partition plates 314 at a predetermined interval therebetween. The partition plate 314 may be arranged directly below the substrate S. The partition plates 314 may be provided above and/or below the substrate S. The partition plates 314 are configured to separate spaces between adjacent substrates S from one another.

The substrates S are stacked and supported by the substrate support structure 300 at a predetermined interval therebetween in the vertical direction. The predetermined interval between the substrates S placed on the substrate support structure 300 is the same as a vertical interval (that is, the pitch described above) between the partition plates 314 fixed to the partition plate support 310. In addition, a diameter of the partition plate 314 is set to be larger than a diameter of the substrate S.

The substrate support structure 300 is configured to support a plurality of substrates (for example, 5 substrates) as the substrates S in a multistage manner in the vertical direction. Further, the present embodiment will be described by way of an example in which 5 substrates are supported by the substrate support structure 300 as the substrates S. However, the present embodiment is not limited thereto. For example, the substrate support structure 300 may be configured to support from 5 substrates to 50 substrates as the substrates S.

For example, in the present specification, a notation of a numerical range such as “5 substrates to 50 substrates” means that a lower limit and an upper limit are contained in the numerical range. Therefore, for example, a numerical range “5 substrates to 50 substrates” means a range equal to or higher than 5 substrates and equal to or less than 50 substrates. The same also applies to other numerical ranges described in the present specification.

The substrate support structure 300 is driven by a vertical driving structure (also referred to as a “vertical driver”) 400 in the vertical direction between the reaction tube 210 and the transfer chamber 217 and in a rotational direction around a center of the substrate S supported by the substrate support structure 300. In other words, the vertical driving structure 400 is used as a rotator (which is a rotating structure) configured to rotate the substrate support structure 300.

The heat insulator 502 is provided below the substrate support structure 300. An exhaust hole 503 is provided at a lower portion of the process chamber 201 of the reaction tube 210 and beside the heat insulator 502 when the substrate support structure 300 is loaded into the reaction tube 210. An exhaust pipe 504 through which the atmosphere (inner atmosphere) of the heat insulating region B is exhausted is connected to the exhaust hole 503.

The transfer chamber 217 is installed below the reaction tube 210 via the manifold 216. In the transfer chamber 217, the substrate S may be transferred to and placed (mounted) on the substrate support structure (hereinafter, may also be simply referred to as a “boat”) 300 by the vacuum transfer robot via the substrate loading/unloading port, or the substrate S may be transferred (or taken) out of the substrate support structure 300 by the vacuum transfer robot.

Inside the transfer chamber 217, the vertical driving structure 400 configured to drive the substrate support structure 300 and the partition plate support 310 in the vertical direction (up-down direction) can be accommodated (or stored). FIG. 1 shows a state in which the substrate support structure 300 is elevated by the vertical driving structure 400 and accommodated in the reaction tube 210. In addition, while the substrate support structure 300 is accommodated in the reaction tube 210, the heat insulator 502 is disposed at a lower portion of the reaction tube 210, and the heat insulator 502 occupies the heat insulating region B provided at the lower portion of the process chamber 201. Thereby, it is possible to reduce a heat conduction to the transfer chamber 217 from the process chamber 201.

For example, the vertical driving structure 400 includes: a rotational driving structure (also referred to as a “rotational driver”) 430 configured to rotate the substrate support structure 300 and the partition plate support 310 together; and a boat vertical driving structure (also referred to as a “boat vertical driver”) 420 configured to drive the substrate support structure 300 in the up-down direction relative to the partition plate support 310.

The rotational driving structure 430 and the boat vertical driving structure 420 are fixed to a base flange 401 serving as a lid supported by a side plate 403 on a base plate 402.

An annular space is provided between a support 441 and a support structure 440. A gas supply pipe 271 is connected to the annular space (which is provided between the support 441 and the support structure 440) below the heat insulator 502. The inert gas is supplied through the gas supply pipe 271 such that the inert gas is supplied to the heat insulator 502 from thereunder.

An O-ring 446 is installed on an upper surface of the base flange 401, and as shown in FIG. 1, by driving a vertical driving motor 410 such that the upper surface of the base flange 401 is elevated to a position where it is pressed against the transfer chamber 217, it is possible to maintain an inside (inner portion) of the reaction tube 210 airtight.

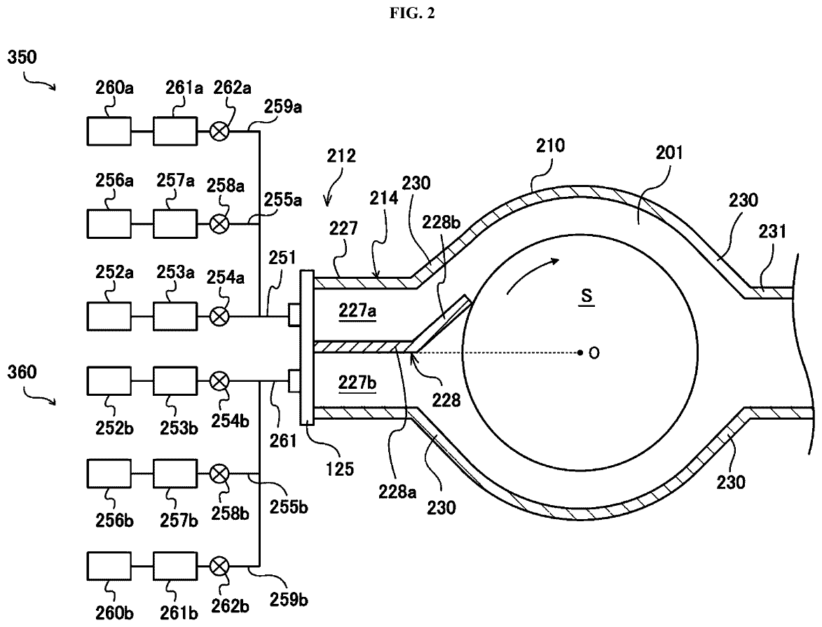

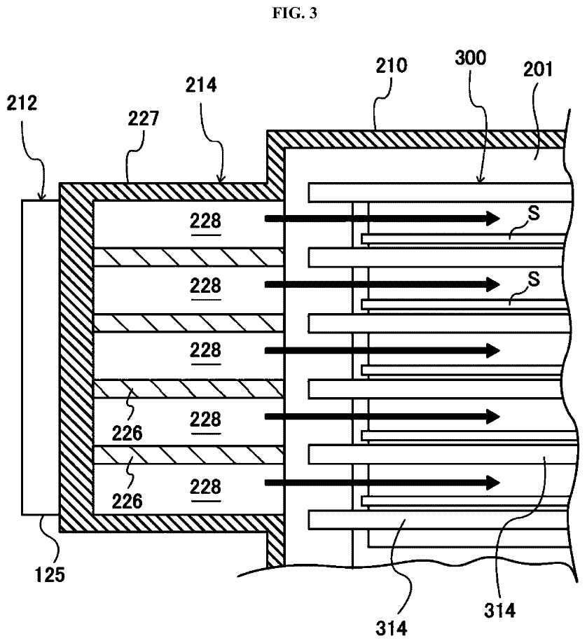

Subsequently, the gas supply structure 212 will be described in detail with reference to FIGS. 2 and 3.

As shown in FIG. 2, the housing 227 and the housing 231 are connected to the upstream side and the downstream side of the reaction tube 210 (of a cylindrical shape), respectively, via a widening structure (which is a width widening structure) 230 of a linear shape. The widening structure 230 is configured to widen from the housing 227 toward the process chamber 201 and from the housing 231 toward the process chamber 201. The reaction tube 210 may include the widening structure 230.

A partition wall 228 serving as a first partition wall of a flat plate shape is provided approximately (substantially) at a center of the partition plate 226 in the housing 227 and approximately perpendicular to the partition plate 226. For example, the partition wall 228 includes: a wall 228a extending approximately parallel to the housing 227; and a wall 228b bending and extending from the wall 228a approximately parallel to the widening structure 230. In other words, a downstream portion of the partition wall 228 extends along a surface of an inner wall of the reaction tube 210 at a rotationally downstream side with reference to the rotational direction of the substrate S. Hereinafter, the surface of the inner wall may also be referred to as an “inner wall surface”.

The partition wall 228 is configured such that the center O of the substrate S is located on a line extending from the wall 228a toward the process chamber 201, and an end of the substrate S is located on an elongated line created by elongating the wall 228b further toward the process chamber 201. In other words, the partition wall 228 is configured such that the elongated line (created by elongating the wall 228b further toward the process chamber 201) includes the center O of the substrate S.

A first flow passage 227a and a second flow passage 227b are defined by the housing 227, the widening structure 230, the partition plate 226 and the partition wall 228. The first flow passage 227a and the second flow passage 227b are configured to be at least partially separated from each other by the partition wall 228. By forming flow passages (that is, the first flow passage 227a and the second flow passage 227b) separated from each other by the partition wall 228 of a flat plate shape but close to each other, it is possible to narrow an overall width thereof while maintaining a width of each of the flow passages. Thereby, it is possible to improve the footprint. In addition, by using the widening structure 230 as a common part of the flow passages, it is possible to supply the gas to a wide area where the substrates S are arranged. Thereby, it is possible to improve a uniformity of a processing of the substrate S within the surface of the substrate S. In addition, the first flow passage 227a and the second flow passage 227b are arranged side by side and approximately horizontally with respect to the substrate S. The first flow passage 227a is arranged at the second flow passage 227b at the rotationally downstream side. The vertical driving structure 400 is configured to rotate the substrate S in a direction along which the gas supplied from the first flow passage 227a flows on an upper surface of the substrate S.

An extension direction of the first flow passage 227a is set so as to form a gas flow path along the inner wall surface of the reaction tube 210 at the rotationally downstream side, and the first flow passage 227a is configured to supply the gas into the process chamber 201 along the inner wall surface of the reaction tube 210 at the rotationally downstream side.

In addition, an extension direction of the second flow passage 227b is set so as to meet with a center of the reaction tube 210 by extending the second flow passage 227b and to form a gas flow path along the inner wall surface of the reaction tube 210 at a rotationally upstream side with reference to the rotational direction of the substrate S. Thereby, the second flow passage 227b is configured to supply the gas into the process chamber 201, and is arranged beside the first flow passage 227a toward the center of the reaction tube 210 along the inner wall surface of the reaction tube 210 at the rotationally upstream side.

In a manner described above, two flow passages are provided to supply the gas (or gases) in two directions into the process chamber 201. Further, it is possible to suppress a vortex flow of the gas on the inner wall surface of the reaction tube 210 at a downstream portion of the first flow passage 227a and at a downstream portion of the second flow passage 227b. That is, it is possible to suppress the vortex flow of the gas around the inner wall surface of the reaction tube 210 at the rotationally upstream side and the rotationally downstream side.

According to the present embodiment, the gas supplied through the first flow passage 227a (which is configured to supply the gas along the inner wall surface of the reaction tube 210 at the rotationally downstream side) is more likely to increase in a temperature and is more likely to be thermally decomposed as compared with the gas supplied through the second flow passage 227b (which is configured to supply the gas toward the center of the substrate S along the inner wall surface of the reaction tube 210 at the rotationally upstream side). By providing the first flow passage 227a at the rotationally more downstream side than the second flow passage 227b, it is possible to prevent the gas (which is thermally decomposed) from entering into the vicinity of an outlet of the first flow passage 227a or the second flow passage 227b as the substrate S rotates.

A gas supply pipe 251 is connected to the first flow passage 227a via a distributor (which is a distribution structure) 125. A gas supply pipe 261 is connected to the second flow passage 227b via the distributor 125.

A first process gas supply source 252a, a mass flow controller (MFC) 253a serving as a flow rate controller (also referred to as a “flow rate control structure”) and a valve 254a serving as an opening/closing valve are sequentially installed at the gas supply pipe 251 in this order from an upstream side to a downstream side of the gas supply pipe 251.

Gas supply pipes 255a and 259a are connected to the gas supply pipe 251 at a downstream side of the valve 254a. A second process gas supply source 256a, a mass flow controller (MFC) 257a and a valve 258a are sequentially installed at the gas supply pipe 255a in this order from an upstream side to a downstream side of the gas supply pipe 255a. An inert gas supply source 260a, a mass flow controller (MFC) 261a and a valve 262a are sequentially installed at the gas supply pipe 259a in this order from an upstream side to a downstream side of the gas supply pipe 259a. A first process gas supply source 252b, a mass flow controller (MFC) 253b and a valve 254b are sequentially installed at the gas supply pipe 261 in this order from an upstream side to a downstream side of the gas supply pipe 261.

Gas supply pipes 255b and 259b are connected to the gas supply pipe 261 at a downstream side of the valve 254b. A second process gas supply source 256b, a mass flow controller (MFC) 257b and a valve 258b are sequentially installed at the gas supply pipe 255b in this order from an upstream side to a downstream side of the gas supply pipe 255b. An inert gas supply source 260b, a mass flow controller (MFC) 261b and a valve 262b are sequentially installed at the gas supply pipe 259b in this order from an upstream side to a downstream side of the gas supply pipe 259b.

A first supplier (which is a first supply structure or a first supply system) 350 is constituted mainly by the gas supply pipe 251 (which is configured to supply the gas into the process chamber 201 through the first flow passage 227a), the MFC 253a, the valve 254a, the gas supply pipe 255a, the MFC 257a, the valve 258a, the gas supply pipe 259a, the MFC 261a and the valve 262a. For example, the first supplier 350 may further include the first process gas supply source 252a, the second process gas supply source 256a and the inert gas supply source 260a.

A second supplier (which is a second supply structure or a second supply system) 360 is constituted mainly by the gas supply pipe 261 (which is configured to supply the gas into the process chamber 201 through the second flow passage 227b), the MFC 253b, the valve 254b, the gas supply pipe 255b, the MFC 257b, the valve 258b, the gas supply pipe 259b, the MFC 261b and the valve 262b. For example, the second supplier 360 may further include the first process gas supply source 252b, the second process gas supply source 256b and the inert gas supply source 260b.

For example, a common first process gas supply source may be used as the first process gas supply source 252a and the first process gas supply source 252b. In addition, a common second process gas supply source may be used as the second process gas supply source 256a and the second process gas supply source 256b. In addition, a common inert gas supply source may be used as the inert gas supply source 260a and the inert gas supply source 260b.

For example, when a first process gas is supplied into the process chamber 201 through the first flow passage 227a and the second flow passage 227b, the first supplier 350 and the second supplier 360 may also be referred to as a “first process gas supplier” which is a first process gas supply structure or a first process gas supply system. For example, when a second process gas is supplied into the process chamber 201 through the first flow passage 227a and the second flow passage 227b, the first supplier 350 and the second supplier 360 may also be referred to as a “second process gas supplier” which is a second process gas supply structure or a second process gas supply system.

The inert gas mainly supplied through the gas supply pipes 259a and 259b acts as a carrier gas for transferring the first process gas or the second process gas when supplying the first process gas or the second process gas, and acts as a purge gas for purging the gas remaining in the reaction tube 210 when purging the reaction tube 210.

Subsequently, a positional relationship between the partition plate 226 and the substrate S will be described with reference to FIG. 3.

As shown in FIG. 3, the partition wall 228 is arranged between each adjacent pair of the partition plates 226 of the upstream side gas guide 214. That is, the first flow passage 227a and the second flow passage 227b are arranged for each of the partition plates 226. The substrate S supported by the substrate support structure 300 is arranged approximately horizontally between each adjacent pair of the partition plates 314. The partition plate 226 and the partition plate 314 corresponding thereto are provided at the same height, and the substrate S is arranged approximately horizontally at a downstream portion of the partition plate 226 corresponding thereto.

That is, the partition plates 226 are disposed at positions corresponding to the substrates S in the housing 227, respectively, with the substrates S supported by the substrate support structure 300. In addition, the first flow passage 227a and the second flow passage 227b are provided at a height corresponding to each of the substrates S. Thereby, it is possible to improve a production efficiency by simultaneously processing the plurality of substrates S.

The process gas such as the first process gas and the second process gas is supplied through the first flow passage 227a and the second flow passage 227b beside the substrate S with the substrates S present in the process chamber 201. The gas supplied through the first flow passage 227a and the second flow passage 227b is supplied to the surface of the substrate S. That is, when viewed from the substrate S, the gas is supplied along the lateral direction of the substrate S. In the present embodiment, since the partition plate 226 is a continuous structure extending in the horizontal direction and provided without a hole, a mainstream of the gas is restrained from flowing in the vertical direction. In addition, the gas supplied through each of the first flow passage 227a and the second flow passage 227b forms a horizontal gas flow passing over the substrate S as shown by arrows in FIGS. 1 and 3. Therefore, the gas flow passing over each of the substrates S is formed in the horizontal direction toward the gas exhaust structure 213 while suppressing the gas flow in the vertical direction.

Subsequently, an exhauster will be described with reference to FIG. 1.

A vacuum pump 284 serving as a vacuum exhaust apparatus is connected to the exhaust pipe 281 via a valve 282 serving as an opening/closing valve and an APC (Automatic Pressure Controller) valve 283 serving as a pressure regulator (also referred to as a “pressure adjusting structure”). Thereby, the reaction tube 210 can be vacuum-exhausted such that a pressure (inner pressure) of the reaction tube 210 reaches and is maintained at a predetermined pressure (also referred to as a “vacuum degree”). An exhauster (which is an exhaust structure or an exhaust system) 280 is constituted by the exhaust pipe 281, the valve 282 and the APC valve 283. In addition, the exhauster 280 may further include the vacuum pump 284.

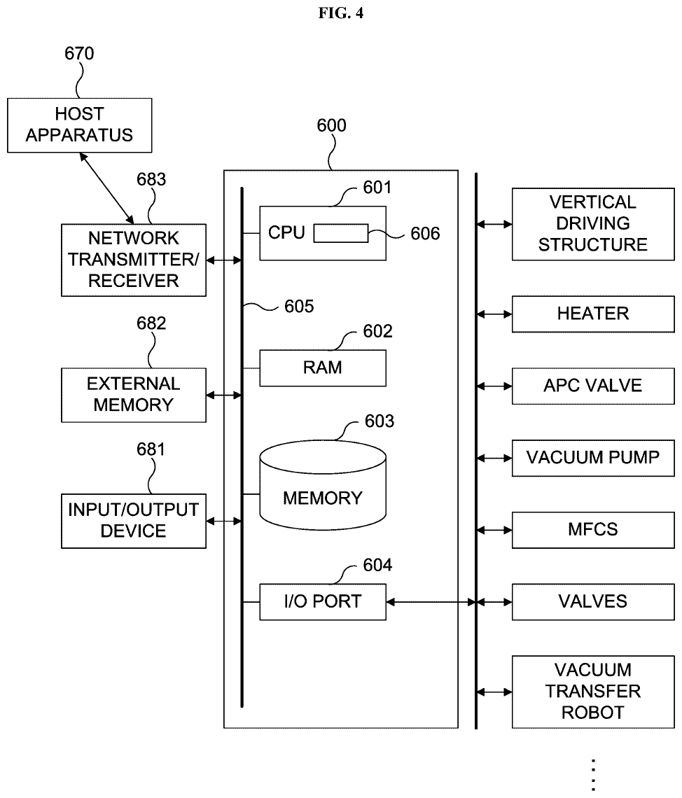

Subsequently, a controller 600 serving as a control structure (also referred to as a “control apparatus”) will be described with reference to FIG. 4. The substrate processing apparatus 10 includes the controller 600 configured to control operations of components constituting the substrate processing apparatus 10.

FIG. 4 is a diagram schematically illustrating a configuration of the controller 600. For example, the controller 600 is constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 can exchange data with the CPU 601 via an internal bus 605. The transmission/reception of the data in the substrate processing apparatus 10 may be performed by an instruction from a transmission/reception instruction controller 606 which is one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod from the host apparatus 670.

For example, the memory 603 may be embodied by a component such as a flash memory and a HDD (Hard Disk Drive). The memory 603 stores process conditions for each type of substrate processing. That is, a control program for controlling the operations of the substrate processing apparatus 10 or a process recipe in which information such as procedures and conditions of the substrate processing is stored may be readably stored in the memory 603.

The process recipe is obtained by combining steps of the substrate processing described later, and acts as a program that is executed by the controller 600 to obtain a predetermined result by performing the steps of the substrate processing described later. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (also referred to as a “work area”) in which the program or the data read by the CPU 601 is temporarily stored.

The I/O port 604 is electrically connected to the components of the substrate processing apparatus 10, which are mentioned above, such as the first supplier 350 and the second supplier 360.

The CPU 601 is configured to read and execute the control program from the memory 603, and is further configured to read the process recipe from the memory 603 in accordance with an instruction such as an operation command inputted from an input/output device 681. The CPU 601 is further configured to be capable of controlling the components such as the first supplier 350 and the second supplier 360 of the substrate processing apparatus 10 to proceed pursuant to the read process recipe.

The CPU 601 includes the transmission/reception instruction controller 606. For example, the controller 600 according to the present embodiment may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to such a method using the external memory 682. For example, the program may be directly provided to the computer by a communication interface such as the Internet and a dedicated line instead of the external memory 682. Further, the memory 603 and the external memory 682 may be embodied by a non-transitory computer-readable recording medium. Hereinafter, the memory 603 and the external memory 682 may be collectively or individually referred to as a “recording medium”.

Thus, in the present specification, the term “recording medium” may refer to the memory 603 alone, may refer to the external memory 682 alone, or may refer to both of the memory 603 and the external memory 682.

### (2) Substrate Processing (Substrate Processing Method)

Hereinafter, as a part of a manufacturing process of a semiconductor device, a substrate processing will be described by way of an example in which a step (film forming process) of forming a film on the substrate S is performed by using the substrate processing apparatus 10 described above. Further, in the following description, the controller 600 controls operations of the components constituting the substrate processing apparatus 10.

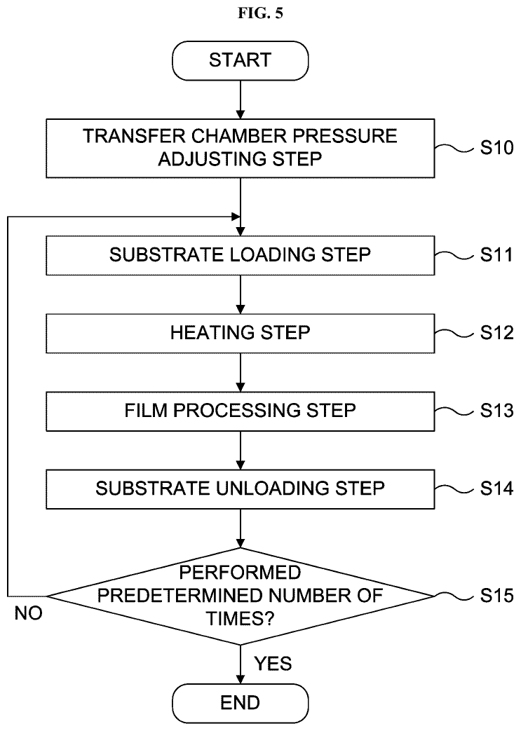

Hereinafter, the film forming process will be described with reference to FIG. 5 by way of an example in which the film is formed on the substrate S by using the first process gas and the second process gas to alternately supply the first process gas and the second process gas.

In the present specification, the term “substrate” may refer to “a substrate itself”, or may refer to “a substrate and a stacked structure (aggregated structure) of a predetermined layer (or layers) or a film (or films) formed on a surface of the substrate”. In the present specification, the term “a surface of a substrate” may refer to “a surface of a substrate itself”, or may refer to “a surface of a predetermined layer (or a predetermined film) formed on a substrate”. Thus, in the present specification, “forming a predetermined layer (or a film) on a substrate” may refer to “forming a predetermined layer (or a film) directly on a surface of a substrate itself”, or may refer to “forming a predetermined layer (or a film) on a surface of another layer (or another film) formed on a substrate”. In the present specification, the terms “substrate” and “wafer” may be used as substantially the same meaning.

### <S10>

A transfer chamber pressure adjusting step S10 will be described. In the present step, a pressure (inner pressure) of the transfer chamber 217 is set to the same level as that of a vacuum transfer chamber (not shown) provided adjacent to the transfer chamber 217.

### <S11>

Subsequently, a substrate loading step S11 will be described.

When an atmosphere (inner atmosphere) of the transfer chamber 217 reaches and is maintained at a vacuum level, a transfer of the substrate S is started. When the substrate S reaches the vacuum transfer chamber, a gate valve is opened. Then, the substrate S is loaded (transferred) into the transfer chamber 217 by the vacuum transfer robot.

In the present step, the substrate support structure 300 stands by in the transfer chamber 217, and the substrate S is transferred to the substrate support structure 300. When a predetermined number of the substrates S are transferred to the substrate support structure 300, the vacuum transfer robot is retracted, and the substrate support structure 300 is elevated by the vertical driving structure 400 to move the substrates S into the process chamber 201 in the reaction tube 210. The substrates S are moved into the process chamber 201 while stacked in the vertical direction.

When moving the substrate S into the reaction tube 210, the surface of the substrate S is positioned so as to be aligned at the same height as the partition plate 226 and the partition plate 232 corresponding thereto.

### <S12>

Subsequently, a heating step S12 will be described.

When the substrate S is loaded into the process chamber 201 in the reaction tube 210, the inner pressure of the reaction tube 210 is controlled (adjusted) to a predetermined pressure and a surface temperature of the substrate S is controlled to a predetermined temperature. The heater 211 is provided adjacent to the substrates S.

### <S13>

Subsequently, a film processing step S13 will be described. The film processing step S13 is performed by performing the following steps S100 to S104 to the substrate S in accordance with the process recipe while the substrates S are stacked on the substrate support structure 300 and accommodated in the process chamber 201.

### <First Process Gas Supply, Step S100>

First, the first process gas is supplied into the reaction tube 210. Specifically, the valves 254a and 254b are opened so as to supply the first process gas into the gas supply pipes 251 and 261. The first process gas whose flow rate is adjusted by the MFCs 253a and 253b is supplied into the reaction tube 210 via the distributor 125, the first flow passage 227a and the second flow passage 227b. Then, the first process gas is exhausted through the space above the substrate S, the downstream side gas guide 215, the gas exhaust structure 213 and the exhaust pipe 281. Further, when the first process gas is being supplied, the valves 262a and 262b may be opened so as to supply the inert gas into the gas supply pipes 251 and 261.

A flow velocity of the gas is different in the vicinity of the center of the reaction tube 210 and in the vicinity of the inner wall of the reaction tube 210. The controller 600 controls the first supplier 350 configured to supply the gas along the inner wall surface of the reaction tube 210, and the second supplier 360 configured to supply the gas in the vicinity of the center of the reaction tube 210. That is, the controller 600 controls the first supplier 350 and the second supplier 360 to control a ratio of the flow rate (also referred to as a “supply amount”) of the first process gas supplied through the first flow passage 227a and the second flow passage 227b. By respectively controlling the flow rate of the gas supplied in the vicinity of the inner wall of the reaction tube 210 and the flow rate of the gas supplied in the vicinity of the center of the reaction tube 210 in a manner described above, it is possible to improve the uniformity of the processing of the substrate S within the surface of the substrate S in accordance with contents of the substrate processing.

In the present step, for example, the APC valve 283 is appropriately adjusted such that the inner pressure of the reaction tube 210 is set to be a pressure within a range from 1 Pa to 3,990 Pa. In the following, for example, a temperature of the heater 211 is adjusted such that a temperature of the substrate S reaches and is maintained at a temperature within a range from 100° C. to 1,500° C., preferably from 400° C. to 800° C.

In the present step, the first process gas is supplied in the horizontal direction from beside the substrate S along the inner wall surface of the reaction tube 210 through the first flow passage 227a (which is in communication with the inside of the reaction tube 210), and is exhausted through the exhaust pipe 281. Simultaneously, the first process gas is also supplied in the horizontal direction from beside the substrate S toward the vicinity of the center of the reaction tube 210 through the second flow passage 227b (which is in communication with the inside of the reaction tube 210), and is exhausted through the exhaust pipe 281. By supplying the first process gas to the process chamber 201 simultaneously through the first flow passage 227a and the second flow passage 227b in a manner described above, it is possible to shorten a process time as compared with a case where the gas is supplied through the first flow passage 227a and the second flow passage 227b at different timings (that is, non-simultaneously).

While the present embodiment is described by way of an example in which the valves 254a and 254b are controlled to be opened and closed simultaneously, the valves 254a and 254b may be controlled to be opened and closed with a time lag or partially simultaneously. That is, the first process gas supplied through the first flow passage 277a and the second flow passage 277b is not limited to being supplied simultaneously, but may be supplied partially simultaneously, or may be supplied alternately instead of simultaneously.

The first process gas supplied to the process chamber 201 forms a gas flow in the upstream side gas guide 214, the space above the substrate S and the downstream side gas guide 215. When forming the gas flow, the first process gas is supplied to the substrate S without a pressure loss above each of the substrates S. As a result, it is possible to uniformly perform the substrate processing between the substrates S. By supplying the first process gas from the gas supply structure 212 to the gas exhaust structure 213 in a manner described above, it is possible to from a gas side flow in the process chamber 201.

In addition, by using the first flow passage 227a and the second flow passage 227b, a fast gas flow flowing in a direction along an inner wall surface of the process chamber 201 and a second gas flow beside the first gas flow to the substrate S are formed. Thereby, it is possible to supply the first process gas to a wide area of the substrate S while suppressing a generation of the vortex flow. As a result, it is possible to improve the uniformity of the processing of the substrate S within the surface of the substrate S.

Further, the first process gas is introduced into the first flow passage 227a and the second flow passage 227b from outside the heater 211 and supplied to the process chamber 201. That is, the first flow passage 227a and the second flow passage 227b are configured to supply the gas introduced from outside the heater 211 (which is located more outward than the process chamber 201) into the process chamber 201. Thereby, it is possible to prevent the first process gas from being thermally decomposed before the first process gas reaches the substrate S.

As the first process gas, for example, a silicon (Si)-containing gas serving as a source gas may be used. As the silicon-containing gas, for example, a gas containing silicon and chlorine (CI) (such as hexachlorodisilane (Si₂Cl₆, abbreviated as HCDS) gas) may be used.

As the inert gas, for example, nitrogen (N₂) gas, helium (He) gas, argon (Ar) gas or the like may be used.

### <Purge, Step S101>

In the present step, the valves 254a and 254b are closed to stop a supply of the first process gas, and the valves 262a and 262b are opened to supply the inert gas serving as the purge gas into the gas supply pipes 251 and 261. When supplying the inert gas, with the valve 282 of the exhaust pipe 281, the APC valve 283 and a valve 506 of the exhaust pipe 504 open, the vacuum pump 284 vacuum-exhausts an atmosphere (inner atmosphere) of the reaction tube 210.

### <Second Process Gas Supply, Step S102>

After a predetermined time has elapsed from a start of the purge (that is, the step S101), the valves 262a and 262b are closed and the valves 258a and 258b are opened to supply the second process gas into the gas supply pipes 251 and 261. The second process gas whose flow rate is adjusted by the MFCs 257a and 257b is supplied into the reaction tube 210 via the distributor 125, the first flow passage 227a and the second flow passage 227b. Then, the second process gas is exhausted through the space above the substrate S, the downstream side gas guide 215, the gas exhaust structure 213 and the exhaust pipe 281. Further, when the second process gas is being supplied, the valves 262a and 262b may be opened so as to supply the inert gas into the gas supply pipes 251 and 261.

In the present step, the second process gas is supplied in the horizontal direction from beside the substrate S along the inner wall surface of the reaction tube 210 through the first flow passage 227a (which is in communication with the inside of the reaction tube 210), and is exhausted through the exhaust pipe 281. In addition, the second process gas is also supplied in the horizontal direction from beside the substrate S toward the vicinity of the center of the reaction tube 210 through the second flow passage 227b (which is in communication with the inside of the reaction tube 210), and is exhausted through the exhaust pipe 281.

For example, in the present step, the inert gas may be supplied to the heat insulating region B through the gas supply pipe 271. The inert gas supplied to the heat insulating region B is exhausted through the exhaust pipe 504 via a lower portion of the heat insulator 502, the upper surface of the base flange 401 and the exhaust hole 503.

In the present step, the valves 258a and 258b may be controlled to be opened and closed simultaneously, may be controlled to be opened and closed with a time lag or partially simultaneously. That is, the second process gas supplied through the first flow passage 277a and the second flow passage 277b is not limited to being supplied simultaneously, but may be supplied partially simultaneously, or may be supplied alternately instead of simultaneously.

As the second process gas, for example, a gas serving as a reactive gas reacting with the first process gas may be used. As the reactive gas, for example, a gas containing hydrogen (H) and nitrogen (N) may be used. As the gas containing hydrogen and nitrogen, for example, a gas such as ammonia (NH₃), diazene (N₂H₂) gas, hydrazine (N₂H₄) gas and N₃H₈ gas may be used.

### <Purge, Step S103>

In the present step, the valves 258a and 258b are closed to stop a supply of the second process gas, and the valves 262a and 262b are opened to supply the inert gas serving as the purge gas into the gas supply pipes 251 and 261. When supplying the inert gas, with the valve 282 of the exhaust pipe 281, the APC valve 283 and the valve 506 of the exhaust pipe 504 open, the vacuum pump 284 vacuum-exhausts the inner atmosphere of the reaction tube 210.

### <Performing Predetermined Number of Times, Step S104>

A cycle (in which the steps S100 to S103 described above are sequentially and non-simultaneously performed in this order) is performed a predetermined number of times (n times, where n is an integer of 1 or more). As a result, it is possible to form a film of a predetermined thickness on the substrate S. In the present embodiment, for example, a silicon nitride (SiN) film is formed.

In addition, in a state where the substrate S loaded into the process chamber 201 is heated, while alternately supplying the first process gas and the second process gas to the process chamber 201, the first process gas, the second process gas and the reaction by-products are exhausted through the exhaust pipe 281 connected to the process chamber 201. When exhausting the first process gas, the second process gas and the reaction by-products, while supplying the inert gas to the heat insulator 502 (which constitutes the heat insulating region B disposed at the lower portion of the process chamber 201) from thereunder, the inert gas is exhausted through the exhaust pipe 504 connected to the heat insulating region B.

### <S14>

Subsequently, a substrate unloading step S14 will be described. In the substrate unloading step S14, the substrate S processed as described above is transferred (unloaded) out of the transfer chamber 217 in the order reverse to that of the substrate loading step S11.

### <S15>

Subsequently, a determination step S15 will be described. In the present step, it is determined whether or not the processing of the substrate S described above (that is, the steps S11 to S14) has been performed a predetermined number of times. When it is determined that the processing has not been performed the predetermined number of times, the substrate loading step S11 is performed again to process a subsequent substrate S to be processed. When it is determined that the processing has been performed the predetermined number of times, the substrate processing is terminated.

While the present embodiment is described by way of an example in which the horizontal gas flow is formed, it is sufficient as long as a main flow of the gas is generally formed in the horizontal direction. Further, a gas flow may be diffused in the vertical direction as long as it does not affect a uniform processing of the plurality of substrates S.

Further, in the above, various expressions such as “the same”, “similar” and the like are used. However, it goes without saying that the expressions described above may mean “substantially the same”.

### (3) Other Embodiments of Present Disclosure

While the technique of the present disclosure is described in detail by way of the first embodiment mentioned above, the technique of the present disclosure is not limited thereto and may be modified in various ways without departing from the scope thereof. For example, the technique of the present disclosure may be modified as shown below. In the substrate processing apparatus according to embodiments described below, substantially the same components as those of the first embodiment described with reference to FIG. 1 will be denoted by like reference numerals, and detailed descriptions thereof will be omitted. That is, only components different from those of the first embodiment mentioned above will be described in detail.

### Second Embodiment

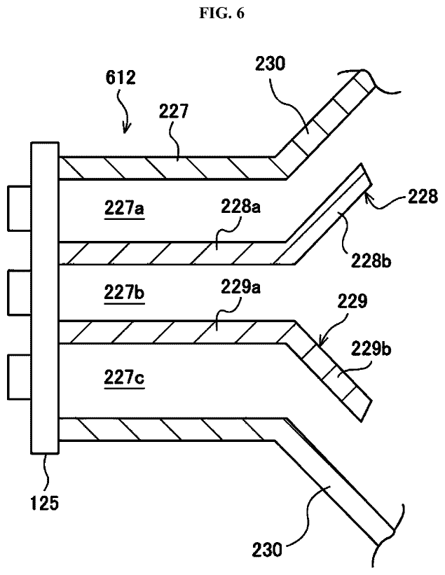

FIG. 6 is a diagram schematically illustrating a gas supply structure 612 according to a second embodiment of the present disclosure.

The partition wall 228 approximately perpendicular to the partition plate 226 and a partition wall 229 serving as a first partition wall of a flat plate shape are provided on the partition plate 226 in the housing 227. For example, the partition wall 228 includes: the wall 228a extending approximately parallel to the housing 227; and the wall 228b bending and extending from the wall 228a approximately parallel to the widening structure 230. In other words, the downstream portion of the partition wall 228 extends along the inner wall surface of the reaction tube 210 at the rotationally downstream side with reference to the rotational direction of the substrate S.

In addition, the partition wall 229 includes: a wall 229a extending approximately parallel to the housing 227; and a wall 229b arranged in a line symmetry with the wall 229b and bending and extending from the wall 229a approximately parallel to the widening structure 230 facing the partition wall 228 from a side opposite to the wall 229a. In other words, a downstream portion of the partition wall 229 extends along the inner wall surface of the reaction tube 210 at the rotationally upstream side with reference to the rotational direction of the substrate S.

The first flow passage 227a and the second flow passage 227b are configured to be at least partially separated from each other by the partition wall 228. In addition, the second flow passage 227b and a third flow passage 227c are configured to be at least partially separated from each other by the partition wall 229.

The second flow passage 227b is arranged beside the first flow passage 227a, and the third flow passage 227c is arranged beside the second flow passage 227b. The first flow passage 227a, the second flow passage 227b and the third flow passage 227c are arranged side by side approximately horizontally, and are provided at the rotationally upstream side in a manner approximately horizontally with respect to the substrate S in a circumferential direction of the substrate S. Among the first flow passage 227a, the second flow passage 227b and the third flow passage 227c, the first flow passage 227a is arranged at the rotationally most downstream side with reference to the rotational direction of the substrate S. Among the first flow passage 227a, the second flow passage 227b and the third flow passage 227c, the third flow passage 227c is arranged at the rotationally most upstream side with reference to the rotational direction of the substrate S. The second flow passage 227b is arranged between the first flow passage 227a and the third flow passage 227c.

That is, the extension direction of the first flow passage 227a is set so as to form the gas flow path along the inner wall surface of the reaction tube 210 at the rotationally downstream side, and the first flow passage 227a is configured to supply the gas into the process chamber 201 along the inner wall surface of the reaction tube 210 at the rotationally downstream side.

In addition, the extension direction of the second flow passage 227b is set so as to meet with the center of the reaction tube 210 by extending the second flow passage 227b, and the second flow passage 227b is configured to supply the gas into the process chamber 201 and is arranged beside the first flow passage 227a toward the center of the reaction tube 210. In other words, the extension direction of the second flow passage 227b is set so as to form a gas flow path toward the center of the substrate S and to supply the gas toward the center of the substrate S.

In addition, an extension direction of the third flow passage 227c is set so as to form a gas flow path along the inner wall surface of the reaction tube 210 at the rotationally upstream side, and the third flow passage 227c is configured to supply the gas into the process chamber 201 along the inner wall surface of the reaction tube 210 at the rotationally upstream side.

In a manner described above, the three flow passages are provided to supply the gas (or gases) in three directions into the process chamber 201. Further, it is possible to suppress the vortex flow of the gas on the inner wall surface of the reaction tube 210 at the downstream portion of the first flow passage 227a and at a downstream portion of the third flow passage 227c. That is, it is possible to suppress the vortex flow of the gas around the inner wall surface of the reaction tube 210 at the rotationally upstream side and the rotationally downstream side. In addition, the first flow passage 227a, the second flow passage 227b and the third flow passage 227c are provided at the height corresponding to each of the substrates S, with the substrates S supported by the substrate support structure 300. Thereby, it is possible to improve the production efficiency by simultaneously processing the plurality of substrates S.

According to the present embodiment, similar to the gas supply structure 212 of the first embodiment described above, the first process gas, the second process gas and the inert gas are supplied to each of the first flow passage 227a and the second flow passage 227b. In addition, a third supplier (which is a third supply structure or a third supply system) configured to supply the inert gas and a third process gas different from the first process gas and the second process gas is connected to the third flow passage 227c so as to supply the third process gas and the inert gas to the third flow passage 227c. As the third process gas, for example, a gaseous mixture (that is, a mixed gas) may be used. As the gaseous mixture, for example, a gaseous mixture of hydrogen (H₂) and oxygen (O₂) may be used.

Specifically, for example, after performing the steps S100 to S104 mentioned above to form the SiN film on the substrate S, the gaseous mixture of the H₂ gas and the O₂ gas is supplied through the third flow passage 227c for a predetermined time. Thereby, the SiN film is oxidized to form a silicon oxide (SiO) film or a silicon oxynitride (SiON) film.

Alternatively, the first process gas and the inert gas may be supplied to each of the first flow passage 227a and the second flow passage 227b, and the second process gas and the inert gas may be supplied to the third flow passage 227c. That is, the third supplier configured to supply the second process gas and the inert gas may be connected to the third flow passage 227c. Thereby, it is possible to supply the second process gas through a flow passage different from that of the first process gas, and it is also possible to respectively perform a processing using the first process gas and a processing using the second process gas.

According to the present embodiment, it is possible to obtain substantially the same effects as in the first embodiment mentioned above.

### Third Embodiment

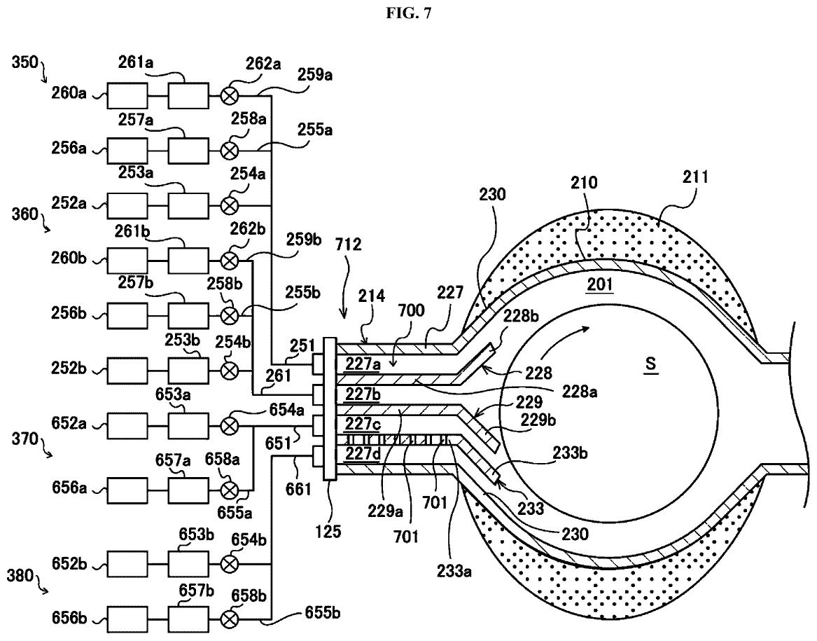

FIG. 7 is a diagram schematically illustrating a gas supply structure 712 according to a third embodiment of the present disclosure.

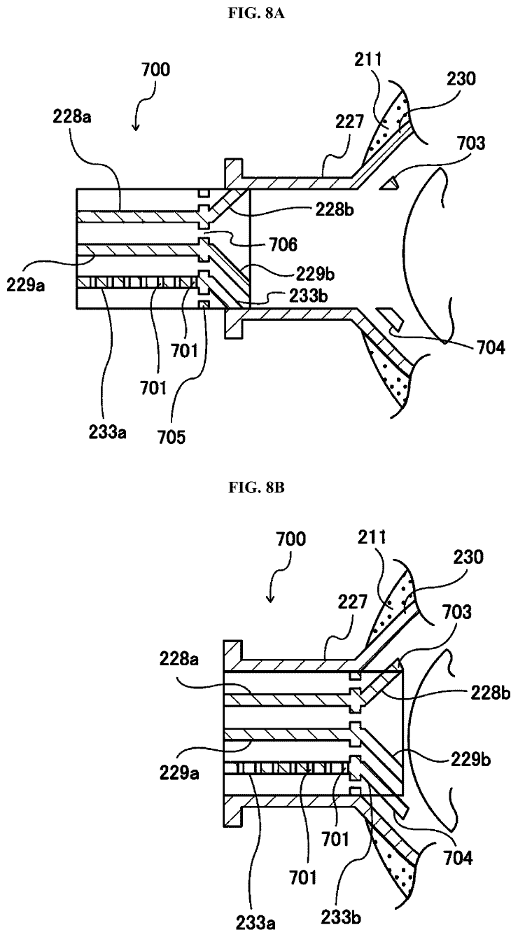

The gas supply structure 712 according to the present embodiment uses a nozzle 700, as shown in FIGS. 8A and 8B, accommodated in the housing 227 provided beside the process chamber 201. That is, the nozzle 700 is detachably accommodated in the housing 227. Thereby, it is possible to easily perform a maintenance operation or a replacement operation for a component (such as the partition wall) constituting the nozzle 700. Further, it is also possible to easily perform a change operation for a shape of a component such as the flow passage. According to the present embodiment, the housing 227 is used as an accommodating structure (housing structure) capable of accommodating the nozzle 700.

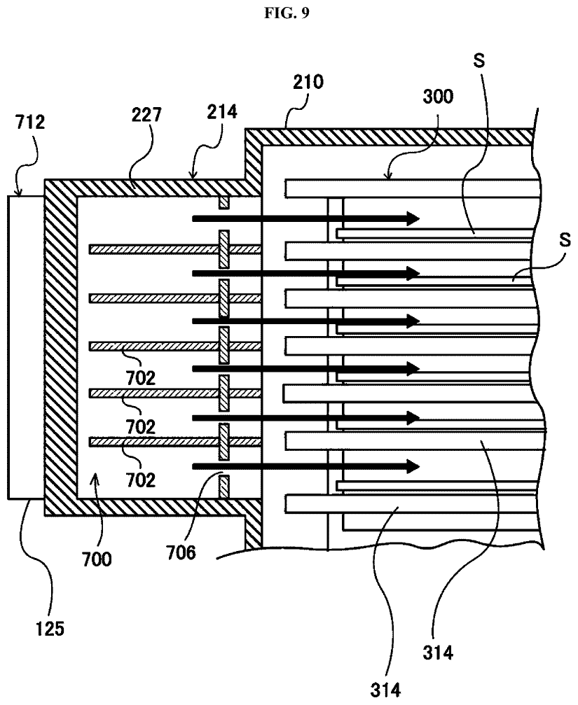

As shown in FIGS. 8B and 9, for example, the nozzle 700 includes: a partition wall 702 serving as a second partition wall of a flat plate shape and arranged between the substrates S, respectively, in a direction approximately horizontally with respect to the substrates S; the partition walls 228 and 229 arranged in parallel to each other and approximately perpendicular to the partition wall 702; and a partition wall 233 serving as a first partition of a flat plate shape. In addition, as shown in FIG. 9, a plurality of partition walls including the partition wall 702 may extend approximately horizontally and be arranged in the vertical direction. Hereafter, the plurality of partition walls including the partition wall 702 may also be simply referred to as “partition walls 702”.

For example, the partition wall 228 includes: the wall 228a extending approximately parallel to the housing 227; and the wall 228b bending and extending from the wall 228a approximately parallel to the widening structure 230. In addition, the partition wall 229 includes: the wall 229a extending approximately parallel to the housing 227; and the wall 229b arranged in a line symmetry with the wall 228b and bending and extending from the wall 229a approximately parallel to the widening structure 230 facing the partition wall 228 from a side opposite to the wall 229a. In other words, the downstream portion of the partition wall 229 extends along the inner wall surface of the reaction tube 210 at the rotationally upstream side. For example, the partition wall 233 includes: a wall 233a extending approximately parallel to the housing 227; and a wall 233b arranged parallel to the wall 229b, bending from the wall 233a in the same direction as the wall 229b of the partition wall 229 and extending approximately parallel to the widening structure 230. In addition, the wall 233a is provided with a plurality of connection holes 701. Alternatively, the partition wall 229 may be of a shape in which the wall 229b is not bent but continuously extends linearly from the wall 229a.

Further, in the process chamber 201, an auxiliary structure 703 is provided as an extension of the wall 228b of the partition wall 228 when the nozzle 700 is accommodated in the housing 227. In addition, an auxiliary structure 704 is provided as an extension of the wall 233b of the partition wall 233 when the nozzle 700 is accommodated in the housing 227. That is, the process chamber 201 includes: the auxiliary structure 703 extending from the partition wall 228 (which is a structure constituting at least a part of the first flow passage 227a and the second flow passage 227b and detachably accommodated in the process chamber 201) and the auxiliary structure 704 extending from the partition wall 233 (which is a structure constituting at least a part of the third flow passage 227c and a fourth flow passage 227d and detachably accommodated in the process chamber 201). By bringing the downstream portion of each flow passage closer to the substrate S in a manner described above, it is possible to suppress the interference between flows of the gas supplied through each of the flow passages.

In other words, when the nozzle 700 is accommodated in the housing 227, the downstream portion of the partition wall 228 extends along the inner wall surface of the reaction tube 210 at the rotationally downstream side. Further, the downstream portion of the partition wall 229 extends along the inner wall surface of the reaction tube 210 at the rotationally upstream side. Further, a downstream portion of the partition wall 233 is configured to bend in the same direction as the downstream portion of the partition wall 229 and extends along the inner wall surface of the reaction tube 210 at the rotationally upstream side.

The first flow passage 227a and the second flow passage 227b are configured to be at least partially separated from each other by the partition wall 228. In addition, the second flow passage 227b and the third flow passage 227c are configured to be at least partially separated from each other by the partition wall 229. Further, the third flow passage 227c and the fourth flow passage 227d are configured to be at least partially separated from each other by the partition wall 233. Specifically, the first flow passage 227a is constituted by the partition wall 702, the housing 227, the partition wall 228 and the auxiliary structure 703. The second flow passage 227b is constituted by the partition wall 702, the partition wall 228, the partition wall 229 and the auxiliary structure 703. The third flow passage 227c is constituted by the partition wall 702, the partition wall 229, the partition wall 233, and the auxiliary structure 704. The fourth flow passage 227d is constituted by the partition wall 702, the partition wall 233, the housing 227 and the auxiliary structure 704.

In addition, the third flow passage 227c and the fourth flow passage 227d communicate with each other through the plurality of connection holes 701 of a circular shape. That is, the connection holes 701 communicate between the third flow passage 227c and the fourth flow passage 227d so as to mix the gas in the third flow passage 227c and the gas in the fourth flow passage 227d.

Further, at the most downstream end portions of the walls 228a, 229a and 233a, a wall 705 is provided approximately perpendicular to the walls 228a, 229a and 233a and the partition wall 702. That is, the first flow passage 227a to the fourth flow passage 227d are partitioned by the wall 705 at the most downstream side portions (of a linear shape) thereof. In addition, a plurality of holes 706 of a circular shape are provided in the wall 705 in a manner corresponding to the first flow passage 227a to the fourth flow passage 227d so as to connect each flow passage to the inside of the process chamber 201. A diameter of each of the holes 706 is set to be large enough to bring about a directionality of the gas flowing through each flow passage. Thereby, it is possible to easily control the gas flow.

In addition, the first flow passage 227a to the fourth flow passage 227d are arranged side by side approximately horizontally, and are provided at the rotationally upstream side approximately horizontally with respect to the substrate S in the circumferential direction of the substrate S. Among the first flow passage 227a to the fourth flow passage 227d, the first flow passage 227a, the second flow passage 227b, the third flow passage 227c and the fourth flow passage 227d are arranged in this order from the most downstream side to a rotationally most upstream side.

That is, the extension direction of the first flow passage 227a is set so as to form the gas flow path along the inner wall surface of the reaction tube 210 at the rotationally most downstream side, and the first flow passage 227a is configured to supply the gas into the process chamber 201 along the inner wall surface of the reaction tube 210 at the rotationally downstream side.

In addition, the extension direction of the second flow passage 227b is set so as to meet with the center of the reaction tube 210 by extending the second flow passage 227b, and the second flow passage 227b is configured to supply the gas into the process chamber 201 and is arranged beside the first flow passage 227a toward the center of the reaction tube 210.

In addition, the extension direction of the third flow passage 227c and an extension direction of the fourth flow passage 227d are set so as to form each gas flow path along the inner wall surface of the reaction tube 210 at the rotationally upstream side. Thereby, it is possible to suppress the vortex flow of the gas around the inner wall surface of the reaction tube 210 at the upstream side and the rotationally downstream side.

The third flow passage 227c and the fourth flow passage 227d are configured to mix the gases respectively supplied from the third flow passage 227c and the fourth flow passage 227d via the connection holes 701 and configured to supply a gaseous mixture thereof to the process chamber 201. That is, by simultaneously supplying the gases through the third flow passage 227c and the fourth flow passage 227d, it is possible to mix the gas supplied through the third flow passage 227c and the gas supplied through the fourth flow passage 227d and to supply the gaseous mixture thereof to the process chamber 201. Thereby, it is possible to efficiently perform the processing of the substrate S using the gaseous mixture of the gases supplied through the third flow passage 227c and the gas supplied through the fourth flow passage 227d.

In a manner described above, the four flow passages are provided to supply the gas (or gases) in four directions into the process chamber 201.

As shown in FIG. 9, the nozzle 700 is provided at the upstream side gas guide 214 in the housing 227. Each of the first flow passage 227a to the fourth flow passage 227d is configured to be at least partially separated from one another vertically by the partition wall 702. For example, the partition wall 702 is configured as a plate of a flat shape. That is, the first flow passage 227a to the fourth flow passage 227d are respectively arranged between each adjacent pair of the partition walls 702. The substrate S supported by the substrate support structure 300 is arranged so as to be disposed approximately horizontally between each adjacent pair of the partition plates 314. The partition wall 702 and the partition plate 314 corresponding thereto are disposed at the same height, and the substrate S is arranged approximately horizontally and adjacent to a downstream portion of each of the partition walls 702. Thereby, it is possible to restrict the gas flow in the vertical direction (up-down direction), and it is also possible to improve the flow directionality of the gas flowing through each flow passage. In addition, by configuring the partition wall 702 as the plate of a flat shape, when the interval (distance) between the substrates S is narrowed, it is possible to arrange more partition walls 702 in the vertical direction. In other words, it is possible to easily increase the number of the substrates S that can be arranged per height.

That is, the partition walls 702 are disposed at positions corresponding to the substrates S in the housing 227, respectively, with the substrates S supported by the substrate support structure 300. In addition, the first flow passage 227a and the fourth flow passage 227d are provided at a height corresponding to each of the substrates S. Thereby, it is possible to improve the production efficiency by simultaneously processing the plurality of substrates S.

According to the present embodiment, in addition to the gas supply pipe 251 being connected to the first flow passage 227a and the gas supply pipe 261 being connected to the second flow passage 227b in the first embodiment mentioned above, a gas supply pipe 651 is connected to the third flow passage 227c and a gas supply pipe 661 is connected to the fourth flow passage 227d.

A third process gas supply source 652a configured to supply the third process gas, a mass flow controller (MFC) 653a and a valve 654a are sequentially installed at the gas supply pipe 651 in this order from an upstream side to a downstream side of the gas supply pipe 651.

A gas supply pipe 655a is connected to the gas supply pipe 651 at a downstream side of the valve 654a. An inert gas supply source 656a, a mass flow controller (MFC) 657a and a valve 658a are sequentially installed at the gas supply pipe 655a in this order from an upstream side to a downstream side of the gas supply pipe 655a.

A third supplier (which is a third supply structure or a third supply system) 370 is constituted mainly by the gas supply pipe 651 (which is configured to supply the process gas into the process chamber 201 through the third flow passage 227c), the MFC 653a, the valve 654a, the gas supply pipe 655a, the MFC 657a and the valve 658a. The third supplier 370 serves as a third process gas supplier (which is a third process gas supply structure or a third process gas supply system). For example, the third supplier 370 may further include the third process gas supply source 652a and the inert gas supply source 656a.

A fourth process gas supply source 652b configured to supply a fourth process gas, a mass flow controller (MFC) 653b and a valve 654b are sequentially installed at the gas supply pipe 661 in this order from an upstream side to a downstream side of the gas supply pipe 661.

A gas supply pipe 655b is connected to the gas supply pipe 661 at a downstream side of the valve 654b. An inert gas supply source 656b, a mass flow controller (MFC) 657b and a valve 658b are sequentially installed at the gas supply pipe 655b in this order from an upstream side to a downstream side of the gas supply pipe 655b.

A fourth supplier (which is a fourth supply structure or a fourth supply system) 380 is constituted mainly by the gas supply pipe 661 (which is configured to supply the process gas into the process chamber 201 through the fourth flow passage 227d), the MFC 653b, the valve 654b, the gas supply pipe 655b, the MFC 657b and the valve 658b. The fourth supplier 380 serves as a fourth process gas supplier (which is a fourth process gas supply structure or a fourth process gas supply system). For example, the fourth supplier 380 may further include the fourth process gas supply source 652b and the inert gas supply source 656b.

The third process gas (which is different from the first process gas and the second process gas) may be supplied from the third process gas supply source 652a. As the third process gas, for example, a gas containing oxygen such as the oxygen (O₂) gas may be used.

The fourth process gas (which is different from the first process gas, the second process gas and the third process gas) to be mixed with the third process gas may be supplied from the fourth process gas supply source 652b. As the fourth process gas, for example, a gas containing hydrogen (H) such as the hydrogen (H₂) gas may be used.

According to the present embodiment, for example, after performing the steps S100 to S104 mentioned above to form the SiN film on the substrate S, the O₂ gas and the H₂ gas are supplied at least partially simultaneously through the third flow passage 227c and the fourth flow passage 227d, respectively, for a predetermined time. Thereby, a gaseous mixture of the O₂ gas and the H₂ gas is supplied to the SiN film on the substrate S, and the SiN film on the substrate S is oxidized to form the silicon oxide (SiO) film or the silicon oxynitride (SiON) film.

Alternatively, instead of providing the connection holes 701 in the partition wall 233, the first process gas and the inert gas may be supplied through each of the first flow passage 227a and the second flow passage 227b, the second process gas and the inert gas may be supplied through the third flow passage 227c, and a gaseous mixture (that is, the third process gas different from the first process gas and the second process gas) may be supplied through the fourth flow passage 227d. Thereby, it is possible to supply the second process gas through a flow passage different from that of the first process gas, and to supply the third process gas through a flow passage different from those of the first process gas and the second process gas. Thus, it is possible to respectively perform the processing using the first process gas, the processing using the second process gas and a processing using the third process gas.

For example, as shown in FIG. 7, the first process gas is introduced from outside the heater 211 into each of the first flow passage 227a, the second flow passage 227b, the third flow passage 227c, and the fourth flow passage 227d, and flows linearly to be supplied into the process chamber 201. That is, the first flow passage 227a, the second flow passage 227b, the third flow passage 227c, and the fourth flow passage 227d are configured to supply the gas introduced from outside the heater 211 (which is located more outward than the process chamber 201) into the process chamber 201. Thereby, it is possible to prevent the first process gas from being thermally decomposed before the first process gas reaches the substrate S.

According to the present embodiment, it is possible to obtain substantially the same effects as in the embodiments mentioned above.

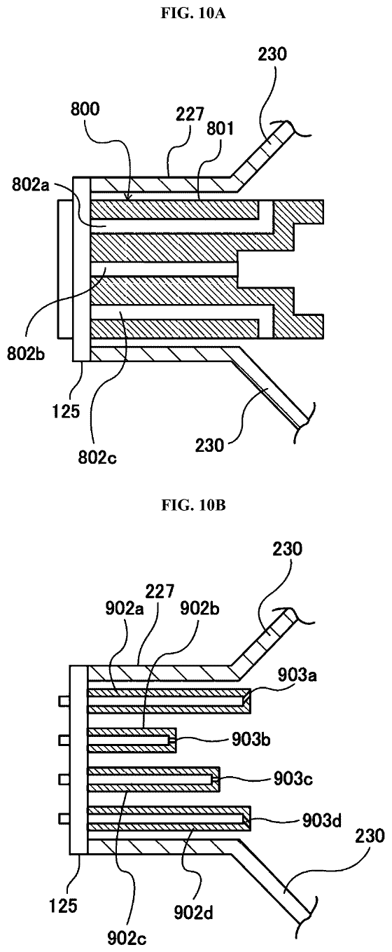

Subsequently, modified examples of the gas supply structure 212 according to the first embodiment of the present disclosure will be described with reference to FIGS. 10A and 10B.

In a modified example shown in FIG. 10A, a nozzle 800 of a block shape is accommodated in the housing 227. The nozzle 800 is provided with three flow passages formed in a housing 801 of a block shape. That is, a first flow passage 802a, a second flow passage 802b and a third flow passage 802c are provided in the housing 801.

The first flow passage 802a extends approximately parallel to the housing 227, opens toward a rotationally downstream side of the widening structure 230, and is configured to supply the gas to the process chamber 201 along the inner wall surface of the reaction tube 210 at the rotationally downstream side. The second flow passage 802b extends approximately parallel to the first flow passage 802a and beside the first flow passage 802a, widens in a stepwise manner, and is configured such that the center of the substrate S is located within an extended region created by extending the second flow passage 802b and such that the gas can be supplied to the center of the substrate S. The third flow passage 802c extends approximately parallel to the second flow passage 802b and beside the second flow passage 802b, opens toward a rotationally upstream side of the widening structure 230 located opposite to the rotationally downstream side where the first flow passage 802a opens, and is configured to supply the gas to the process chamber 201 along the inner wall surface of the reaction tube 210 at the rotationally upstream side.

According to the present modified example, similar to the gas supply structure 612 of the second embodiment mentioned above, the first process gas, the second process gas and the inert gas are supplied to each of the first flow passage 802a and the second flow passage 802b, and the third process gas (which is different from the first process gas and the second process gas) and the inert gas are supplied to the third flow passage 802c.

In a modified example shown in FIG. 10B, four nozzles 902a, 902b, 902c and 902d of different lengths are accommodated in the housing 227. That is, four flow passages are provided in the housing 227. The nozzles 902a to 902d are arranged in parallel to one another in the housing 227.

The nozzle 902a extends approximately parallel to the housing 227, and is provided with a hole 903a at a downstream side end portion of the nozzle 902a. The hole 903a opens obliquely at an angle toward the widening structure 230. The nozzle 902a is configured to supply the gas to the process chamber 201 along the inner wall surface of the reaction tube 210 at the rotationally downstream side. The nozzle 902b is arranged beside the nozzle 902a, is shorter than the nozzles 902a, 902c and 902d, and is provided with a hole 903b at a downstream side end portion of the nozzle 902b. The hole 903b opens toward the vicinity of the center of the reaction tube 210. The nozzle 902b is configured to supply the gas into the vicinity of the center of the reaction tube 210. The nozzle 902c is arranged beside the nozzle 902b, is longer than the nozzle 902b, is shorter than the nozzles 902a and 902d, and is provided with a hole 903c at a downstream side end portion of the nozzle 902c. The hole 903c opens toward the vicinity of the center of the reaction tube 210. The nozzle 902c is configured to supply the gas from a downstream side of the nozzle 902b into the vicinity of the center of substrate S. The nozzle 902d is arranged beside the nozzle 902c, and a length of the nozzle 902d is the same as that of the nozzle 902a. The nozzle 902d is provided with a hole 903d. The hole 903d opens toward a rotationally upstream side of the widening structure 230 located opposite to the rotationally downstream side where the nozzle 902a opens. The nozzle 902d is configured to supply the gas to the process chamber 201 along the inner wall surface of the reaction tube 210 at the rotationally upstream side.

The nozzles 902a to 902d are used as the first flow passage to the fourth flow passage, respectively.

According to the present modified example, similar to the gas supply structure 712 of the third embodiment mentioned above, the first process gas, the second process gas and the inert gas are supplied to each of the nozzle 902a serving as the first flow passage and the nozzle 902b serving as the second flow passage, the third process gas (which is different from the first process gas and the second process gas) and the inert gas are supplied to the nozzle 902c serving as the third flow passage. In addition, the fourth process gas (which is different from the first process gas, the second process gas and the third process gas and which is to be mixed with the third process gas) and the inert gas are supplied to the nozzle 902d serving as the fourth flow passage.

Even in a configuration using the nozzle 800 or the nozzles 902a to 902d according to the modified examples mentioned above, it is possible to obtain substantially the same effects as in the embodiments mentioned above.

For example, the embodiments and the modified examples mentioned above are described by way of an example in which two to four flow passages are used. However, the technique of the present disclosure is not limited thereto. That is, even when five or more flow passages are used, it is possible to obtain substantially the same effects as in the embodiments mentioned above.

For example, in the gas supply structure 212 and the gas supply structure 612 mentioned above, similar to the nozzle 700 mentioned above, the partition wall 702 of a flat plate shape may be provided to separate at least a part of each flow passage into upper and lower portions such that the flow passages can be attached and detached inside the housing 227 provided beside the process chamber 201, and the flow passages are separated from one another in a manner approximately perpendicular to the partition wall 702. Even in such a case, it is possible to obtain substantially the same effects as in the embodiments mentioned above.

For example, the embodiments mentioned above are described by way of an example in which the film is formed using the HCDS gas as the first process gas and the NH₃ gas as the second process gas in the film processing step S13. However, the technique of the present disclosure is not limited thereto.

For example, the embodiments mentioned above are described by way of an example in which the gases supplied through the first flow passage and the second flow passage to the substrate S are simultaneously supplied to the process chamber 201 in accordance with the process recipe in the film processing step S13. However, the technique of the present disclosure is not limited thereto. That is, the gas supplied through the first flow passage and the gas supplied through the second flow passage may be supplied at different timings, or may be supplied partially simultaneously.

In addition, the technique of the present disclosure may also be preferably applied when at least one among the first process gas and the second process gas is stored in a tank serving as a storage and supplied in a large amount at once to the substrate S in the film processing step S13. That is, even in a case where at least one among the first process gas and the second process gas is stored in the tank and pressurized, and a valve serving as an opening/closing valve provided at a downstream side of the tank is opened to supply the gas to the substrate S, it is possible to obtain substantially the same effects as in the embodiments mentioned above.

For example, the embodiments mentioned above are described by way of an example in which the film forming process is performed as the substrate processing performed by the substrate processing apparatus 10. However, the technique of the present disclosure is not limited thereto. That is, instead of or in addition to the film forming process exemplified above, the technique of the present disclosure can be preferably applied even when film forming processes other than the film forming process exemplified above are performed.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

Further, the embodiments and the modified examples mentioned above may be appropriately combined. The process procedures and the process conditions of each combination thereof may be substantially the same as those of the embodiments or the modified examples mentioned above.

As described above, according to some embodiments of the present disclosure, it is possible to suppress the variations in the supply amount of the process gas within the surface of the substrate.

What is claimed is:

1. A substrate processing apparatus comprising:
a process chamber in which a substrate is processed;
a substrate support configured to support the substrate;
a first flow passage through which a gas is supplied to the process chamber along an inner wall surface of the process chamber; and
a second flow passage, through which the gas is supplied to the process chamber, arranged beside the first flow passage,
wherein the second flow passage is configured such that a center of the process chamber is located within an extended region created by extending the second flow passage further toward the process chamber.

2. The substrate processing apparatus of claim 1, further comprising:
a first process gas supplier configured to be capable of supplying a first process gas into the process chamber through the first flow passage and the second flow passage; and
a controller configured to be capable of controlling at least the first process gas supplier.

3. The substrate processing apparatus of claim 1, wherein the first flow passage and the second flow passage are configured such that a center of the substrate is located within an elongated line created by elongating a wall surface constituting the first flow passage and the second flow passage further toward the process chamber.

4. The substrate processing apparatus of claim 1, further comprising
a rotator configured to rotate the substrate support,
wherein the rotator is further configured to rotate the substrate in a direction along which the gas supplied from the first flow passage flows on an upper surface of the substrate.

5. The substrate processing apparatus of claim 1, wherein at least one of the first flow passage or the second flow passage comprises a widening structure whose width increases toward the process chamber.

6. The substrate processing apparatus of claim 1, wherein a first structure constituting at least a part of the first flow passage and a second structure constituting at least a part of the second flow passage are detachably accommodated in a housing structure provided beside the process chamber.

7. The substrate processing apparatus of claim 6, wherein the process chamber comprises an auxiliary structure detachably accommodated in the process chamber and extending from at least one of the first structure or the second structure.

8. The substrate processing apparatus of claim 1, wherein the substrate support is further configured to support one or more substrates, and
wherein the first flow passage and the second flow passage are located at a height corresponding to each of the substrate and the one or more substrates.

9. The substrate processing apparatus of claim 1, further comprising:
a heater installed outside the process chamber and configured to heat the substrate,
wherein an end of the first flow passage opposite to the process chamber and an end of the second flow passage opposite to the process chamber are located more outward than the heater when viewed from the center of the process chamber.

10. The substrate processing apparatus of claim 1, further comprising
a third flow passage, through which another gas is supplied to the process chamber, arranged beside the second flow passage.

11. The substrate processing apparatus of claim 10, wherein a first structure constituting at least a part of the first flow passage, a second structure constituting at least a part of the second flow passage and a third structure constituting at least a part of the third flow passage are detachably accommodated in a housing structure provided beside the process chamber.

12. The substrate processing apparatus of claim 11, wherein the process chamber comprises an auxiliary structure detachably accommodated in the process chamber and extending from at least one of the first structure, the second structure or the third structure.

13. The substrate processing apparatus of claim 10, further comprising:
a fourth flow passage, through which another gas is supplied to the process chamber, arranged beside the third flow passage.

14. The substrate processing apparatus of claim 13, wherein a first structure constituting at least a part of the first flow passage, a second structure constituting at least a part of the second flow passage, a third structure constituting at least a part of the third flow passage and a fourth structure constituting at least a part of the fourth flow passage are detachably accommodated in a housing structure provided beside the process chamber.

15. The substrate processing apparatus of claim 14, wherein the process chamber comprises an auxiliary structure detachably accommodated in the process chamber and extending from at least one of the first structure, the second structure, the third structure constituting or the fourth structure.

16. The substrate processing apparatus of claim 1, wherein the first flow passage and the second flow passage are configured to be at least partially separated from each other by a partition wall of a flat plate shape.

17. The substrate processing apparatus of claim 13, further comprising:
a first process gas supplier configured to be capable of supplying a first process gas to the process chamber through the first flow passage and the second flow passage;
a third process gas supplier configured to be capable of supplying a third process gas to the process chamber through the third flow passage;
a fourth process gas supplier configured to be capable of supplying a fourth process gas to the process chamber through the fourth flow passage;
a connection hole connecting the third flow passage and the fourth flow passage so as to mix the third process gas in the third flow passage and the fourth process gas in the fourth flow passage; and
a controller configured to be capable of controlling at least the first process gas supplier, the third process gas supplier and the fourth process gas supplier,
wherein the controller is further configured to be capable of controlling the third process gas supplier and the fourth process gas supplier such that the third process gas and the fourth process gas are supplied to the process chamber at least partially at a time.

18. A substrate processing method using a substrate processing apparatus comprising: a process chamber in which a substrate is processed; a substrate support configured to support the substrate; a first flow passage through which a gas is supplied to the process chamber along an inner wall surface of the process chamber; and a second flow passage, through which the gas is supplied to the process chamber, arranged beside the first flow passage, wherein the second flow passage is configured such that a center of the process chamber is located within an extended region created by extending the second flow passage further toward the process chamber, the substrate processing method comprising:
(a) supplying the gas to the substrate through the first flow passage; and
(b) supplying the gas to the substrate through the second flow passage.

19. A method of manufacturing a semiconductor device, comprising:
the substrate processing method of claim 18.

20. A non-transitory computer-readable recording medium storing a program that causes a substrate processing apparatus comprising: a process chamber in which a substrate is processed; a substrate support configured to support the substrate; a first flow passage through which a gas is supplied to the process chamber along an inner wall surface of the process chamber; and a second flow passage, through which the gas is supplied to the process chamber, arranged beside the first flow passage, wherein the second flow passage is configured such that a center of the process chamber is located within an extended region created by extending the second flow passage further toward the process chamber, by a computer, to perform:
(a) supplying the gas to the substrate through the first flow passage; and
(b) supplying the gas to the substrate through the second flow passage.
